(19) United States
(12) Patent Application Publication
(10) Pub. No.: US 2016/0138580 A1
(43) Pub. Date: May 19, 2016

(54) MEMS-BASED ACTIVE COOLING SYSTEM

(71) Applicants: Eran FINE, Tel Aviv (IL); Viacheslav KRYLOV, Holon (IL); Yosi SHACHAM-DIAMAND, Zichron- Ya'acov (IL); Ekaterina AXELROD, Jerusalem (IL); Mordechai BEN-DAVID, Tel Aviv (IL); Ziv HERMON, Modiin-Maccabim-Reut (IL)

(72) Inventors: Eran FINE, Tel Aviv (IL); Viacheslav KRYLOV, Holon (IL); Yosi SHACHAM-DIAMAND, Zichron- Ya'acov (IL); Ekaterina AXELROD, Jerusalem (IL); Mordechai BEN-DAVID, Tel Aviv (IL); Ziv HERMON, Modiin-Maccabim-Reut (IL)

(21) Appl. No.: 14/936,107

(22) Filed: Nov. 9, 2015

Related U.S. Application Data
(60) Provisional application No. 62/077,626, filed on Nov. 10, 2014.

(51) Int. Cl. F04B 43/04; H01L 41/29; H01L 41/331; F04D 33/00

(52) U.S. Cl. CPC F04B 43/046; F04D 33/00; H01L 41/29; H01L 41/331

(57) ABSTRACT

In various embodiments, a cooling device for dissipating heat generated in an electronic or electrochemical device includes a substrate, multiple benders arranged on the substrate, and supply circuitry for supplying an electric field to actuate the benders for causing movement thereof, thereby producing an air flow.

### CROSS-REFERENCE TO RELATED APPLICATION

This application claims priority to and the benefit of, and incorporates herein by reference in its entirety, U.S. Provisional Patent Application No. 62/077,626, which was filed on Nov. 10, 2014.

### FIELD OF THE INVENTION

In various embodiments, the present invention relates generally to active cooling systems and methods for manufacturing the active cooling systems using micro-electromechanical system (MEMS) technology.

### BACKGROUND

As semiconductor manufacturing technology has evolved to permit ever-greater microprocessor core frequencies and power consumption, heat extraction has emerged as a key factor limiting continued progress. If waste heat cannot be removed from a microprocessor continuously, reliably and without excessive power consumption that would itself contribute to the heat load, the device cannot be used; it would quickly succumb to the heat it generates. Heat removal is even more challenging in mobile environments, which tend to involve thin, light form factors. Indeed, mobile platforms often operate at reduced frequencies precisely to reduce power and limit heat generation. That poses a challenge for manufacturers, as consumers demand more from their mobile devices—sleeker form factors, faster connectivity, richer and bigger displays, and better multimedia capabilities.

Beyond the basic mechanical and thermodynamic challenges of heat removal, consumer acceptance of cooling technologies requires quiet operation; how much noise a user will tolerate depends on the device, but certainly the aggressive noise of a PC fan would be unacceptable in a mobile device used as a phone. Still, fans are widely deployed in many heat-producing devices, often in conjunction with heat sinks or similar designs for increasing the surface area and thermal conductivity of the device to be cooled. For example, fins are often used to improve heat transfer. In electronic devices with severe space constraints, the shape and arrangement of fins must be optimized to maximize the heat-transfer density.

Another cooling approach utilizes synthetic air jets produced by vortices that are generated by alternating brief ejections and suctions of air across an opening such that the net (time-averaged) mass flux is zero. Synthetic jet air movers have no moving parts and are thus maintenance-free. Due to the limited overall flow rates that may be achieved with practical synthetic jet air systems, these are usually deployed at the chip level rather than at the system level.

Electrostatic fluid accelerators (EFAs) represent still another currently used approach to device cooling. An EFA is a device that pumps a fluid (such as air) without any moving parts. Instead of using rotating blades, as in a conventional fan, an EFA uses an electric field to propel electrically charged air molecules. Because air molecules normally have no net charge, the EFA creates some charged molecules, or ions, first. Thus an EFA ionizes air molecules, uses those ions to push many more neutral molecules in a desired direction, and then recaptures and neutralizes the ions to eliminate any net charge. These systems involve high operating voltages and the risk of undesirable electrical events, such as sparking and/or arcing. Unintended contact made with one of the electrodes can result in potentially dangerous physical injury. Accordingly, there is a need for safe and reliable approaches to dissipating heat generated in electronic devices.

### SUMMARY

Embodiments of the present invention utilize micro-electromechanical system (MEMS) technology and electroactive polymers (EAPs) to provide flexible benders operable to form, collectively, a cooling system for devices such as computers, smart phones, tablets, lighting systems, batteries, and other applications. In a representative embodiment, the cooling system includes a series of flexible fins or benders that can be repeatedly actuated to create an air flow for dissipating heat. In various embodiments, each bender component includes a fan member, an anchor affixed to a substrate, and a flexible beam connecting the fan member to the anchor. An EAP actuator overlies the beam. In these embodiments, application of an electric field to the EAP actuator causes it to contract, tugging the normally flat beam so that it bends, and consequently causing the fan member to move. The electric fields applied to the various EAP actuators may have the same or different amplitudes, frequencies, and/or phases such that the fan members vibrate with the same or different amplitude, frequencies, and/or phases in a simultaneous, sequential, or any desired manner to collectively produce a desired air flow parameter (e.g., a flow rate or a flow direction). For example, the benders may be actuated at the same amplitude and frequency but at different phases such that the movements thereof collectively form a “wave” travelling along a predetermined direction. Alternatively, a selected subset of the benders may be actuated simultaneously at the same amplitude to achieve a predetermined flow rate and/or flow direction. The cooling systems described herein may thus produce a desired air flow that can efficiently, reliably, and safely dissipate heat generated in the device, thereby optimizing the performance and improving the lifetime thereof. In addition, the use of MEMS technology advantageously allows the cooling system to be manufactured in a sufficiently compact size such that it can be accommodated in devices having severe space constraints.

Accordingly, in one aspect, the invention pertains to a cooling device including a substrate and multiple benders arranged on the substrate; each bender includes (i) a fan member, (ii) a beam, and (iii) one or more electroactive actuators associated with the beam for transmitting force thereto. In one implementation, the beam is anchored to the substrate, and the fan member and the electroactive actuator(s) are unanchored to the substrate. In addition, the cooling device includes supply circuitry for supplying a time-varying signal to the electroactive actuator(s); the fan members vibrate at a frequency corresponding to the signal and collectively produce an air flow. The electroactive actuator(s) may be mechanically coupled to the beam. In one implementation, the beam is made of an electroactive polymer.

In one embodiment, the benders all have a common orientation on the substrate so that the flows produced by the benders are substantially additive. In another embodiment, at least some of the benders have different orientations on the substrate. Additionally, the vibration of the benders may be synchronized or unsynchronized. The device may further include control circuitry. The control circuitry may selectively operate a subset of the benders to achieve a predetermined flow parameter (e.g., a flow rate or a flow direction) and/or for independently operating each of the benders to achieve the predetermined flow parameter. Some of the time-varying signals applied to the electroactive actuators may have a phase and/or an amplitude difference.

In various embodiments, the control circuitry may group the benders into multiple subsets of the benders and independently operate each subset to achieve the predetermined flow parameter. Vibration of the benders in each subset of the benders may be synchronized. Additionally or alternatively, vibration of the benders between different subsets of the benders may be synchronized. Further, at least some of the time-varying signals applied to the subsets of the electroactive actuators have a phase or an amplitude difference.

Each electroactive actuator may include multiple electroactive layers and multiple conductive layers. Alternatively, each electroactive actuator may include an electroactive layer and multiple conductive lines embedded therein. In one embodiment, the device further includes a flow sensor for detecting a parameter associated with the produced air flow. In another embodiment, the device includes a temperature sensor for detecting the temperature associated with the cooling device, a platform thereof, or an ambient environment.

In another aspect, the invention relates to a method of cooling a system. In various embodiments, the method includes providing a cooling device having a substrate and multiple benders arranged on the substrate, each bender including (i) a fan member, (ii) a beam, and (iii) one or more electroactive actuators associated with the beam for transmitting force thereto, the beam being anchored to the substrate, and the fan member and the electroactive actuator being unanchored to the substrate; and applying a time-varying signal to the electroactive actuator(s) to cause vibration of the fan members at a frequency corresponding to the signal and collectively produce an air flow.

Another aspect of the invention relates to a method of manufacturing a cooling device. In various embodiments, the method includes providing a substrate; and forming, on the substrate, multiple benders, each including (i) a fan member, (ii) a beam, and (iii) one or more electroactive polymers associated with the beam for transmitting force thereto. The benders may be formed utilizing micro-electromechanical system (MEMS) technology. In one implementation, the substrate includes a semi-conductor wafer, metal, glass, quartz, ceramic, and/or a polymer.

In one embodiment, formation of the benders includes the steps of: forming a first electrode layer on a first side of the substrate; forming a hard mask on a second side of the substrate; depositing the electroactive polymer(s) on the first electrode layer; forming a second electrode layer; releasing a portion of the substrate on the second side thereof; releasing the electroactive polymer(s); and separating the benders. The first electrode layer and/or the second electrode layer is formed by a photolithography process, a metal etching process, a lift-off process, and/or a laser cut. In addition, the electroactive polymer(s) is(are) deposited by spin coating, spray coating, rolling and/or nanoimprint lithography.

In another embodiment, formation of the benders includes the steps of: depositing a sacrificial layer on the substrate; forming a polymer sheet layer; forming a first electrode layer; depositing the electroactive polymer(s) on the first electrode layer; forming a second electrode layer; forming a via; separating the benders; and removing the a sacrificial layer to release the benders.

In yet another embodiment, formation of the benders includes the steps of: depositing a sacrificial layer on the substrate; forming a polymer sheet layer; forming a first electrode layer; depositing the electroactive polymer(s) on the first electrode layer; forming a second electrode layer; forming a via; separating the benders; and removing the a sacrificial layer to release the benders.

In some embodiments, formation of the benders includes the steps of: forming a first electrode layer on the substrate; depositing the electroactive polymer(s) on the first electrode layer; forming a second electrode layer; and separating the benders.

As used herein, the terms “approximately,” “roughly,” and “substantially” mean ±10%, and in some embodiments, ±5%. Reference throughout this specification to “one example,” “an example,” “one embodiment,” or “an embodiment” means that a particular feature, structure, or characteristic described in connection with the example is included in at least one example of the present technology. Thus, the occurrences of the phrases “in one example,” “in an example,” “one embodiment,” or “an embodiment” in various places throughout this specification are not necessarily all referring to the same example. Furthermore, the particular features, structures, routines, steps, or characteristics may be combined in any suitable manner in one or more examples of the technology. The headings provided herein are for convenience only and are not intended to limit or interpret the scope or meaning of the claimed technology.

### BRIEF DESCRIPTION OF THE DRAWINGS

In the drawings, like reference characters generally refer to the same parts throughout the different views. Also, the drawings are not necessarily to scale, with an emphasis instead generally being placed upon illustrating the principles of the invention. In the following description, various embodiments of the present invention are described with reference to the following drawings, in which:

FIGS. 1A and 1B schematically illustrate an exemplary cooling system in accordance with various embodiments of the present invention;

FIGS. 1C and 1D schematically illustrate a first exemplary cooling system in accordance with various embodiments of the present invention;

FIGS. 2A and 2B schematically depict a second exemplary cooling system in accordance with various embodiments of the present invention;

FIG. 3 schematically depicts a third exemplary cooling system in accordance with various embodiments of the present invention;

FIGS. 4A-D schematically depict a fourth exemplary cooling system in accordance with various embodiments of the present invention;

FIG. 4E is a schematic sectional side view of movement of the fourth exemplary cooling system in accordance with various embodiments of the present invention;

FIG. 5A-G show steps in the fabrication of a cooling system in accordance with one embodiment of the present invention;

FIGS. 6A-I show steps in the fabrication of a cooling system in accordance with another embodiment of the present invention;

FIGS. 7A and 7B show steps in the fabrication of a cooling system in accordance with still another embodiment of the present invention;

FIG. 8A is a schematic sectional side view of an EAP actuator having multiple horizontal conductive layers in accordance with various embodiments of the present invention; and

FIGS. 8B and 8C are a schematic sectional side view and a top view, respectively, of an EAP actuator having multiple vertical conductive lines in accordance with various embodiments of the present invention.

### DETAILED DESCRIPTION

### A. Cooling Systems for Heat Dissipation

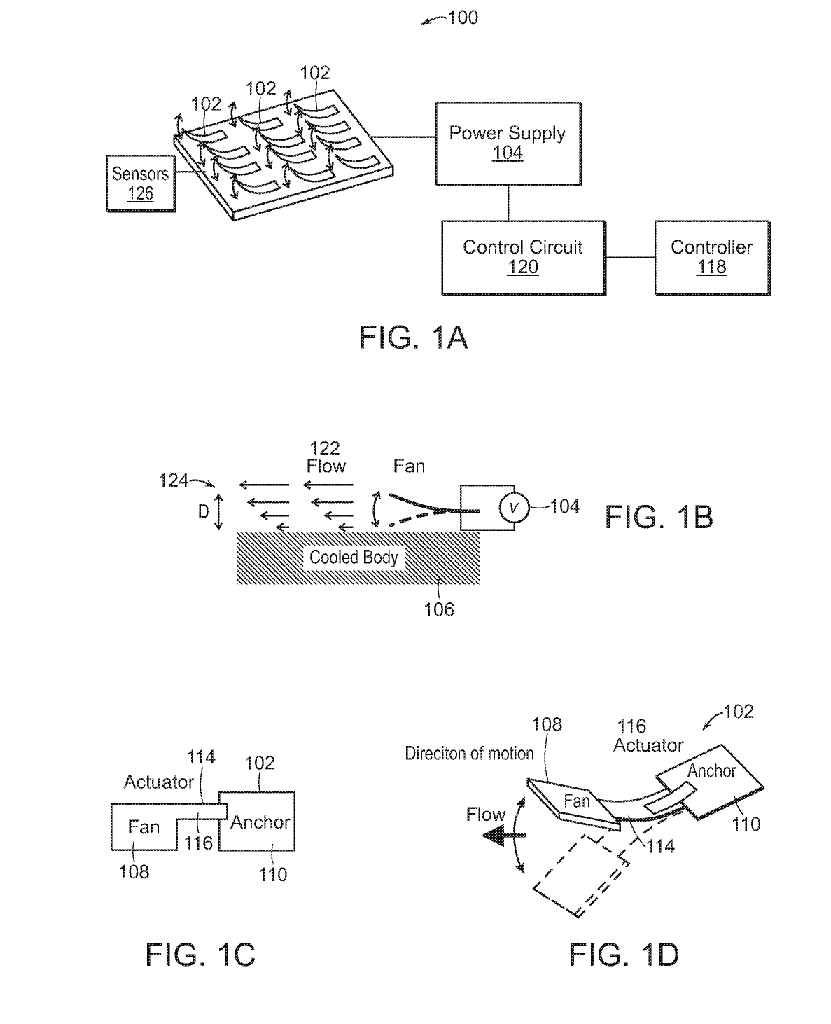

Refer first to FIGS. 1A and 1B, which illustrate a cooling system 100 having a series of flexible benders (or fins) 102 and a power supply 104 for supplying power (i.e., a voltage or a current) to actuate the benders 102. The power supply 104 may be provided by any appropriate power source, such as an AC mains supply, other conventional AC supply, or a conventional DC supply. The power supply 104 may also be part of the cooled system 100, e.g., the battery of a mobile platform. The benders 102 may be arranged in an array at the surface of a cooled body 106 (i.e., a component generating heat that requires cooling) or at positions close thereto. The array may comprise or consist of a single row, a single column or a matrix of the benders 102. In some embodiments, each of the benders 102 in the array has a common orientation such that the air flows produced by each of the benders 102 are substantially additive. In alternative embodiments, the benders 102 may be arranged in a pattern or without coordination, i.e., they need not be spaced regularly or arranged in a regular pattern. The array of benders 102 may be disposed on a planar surface, as illustrated, or a curved or otherwise shaped surface that can be accommodated by the space close to the cooled body 106 in an electronic device (e.g., a computer, a smart phone, a tablet, a lighting system, a battery, etc.). The dimensions of the bender array may vary, depending on the application, between a few hundred micrometers to a few millimeters.

Referring to FIGS. 1C and 1D, in various embodiments, each bender 102 includes a fan member 108, an anchor 110 affixed to a common substrate 112, and a flexible beam 114 connecting the fan member 108 to the anchor 110. In addition, each bender 102 may include an EAP actuator 116 overlaying and mechanically coupled to the beam 114 for deflecting the bender 102. The actuator 116 may cover a portion (e.g., 50%) of the top surface of the flexible beam 114 or, in some embodiments, the entire top surface of the beam 114. In one embodiment, the beam 114 itself is an EAP actuator 116. In general, the size of the fan member 108 may range from 100 μm to a few mm (e.g., 1 to 10 mm), and the thickness of the fan member 108 may vary from a few μm (e.g., less than 10 μm) up to 1 mm.

Referring again to FIGS. 1A and 1B, in various embodiments, the cooling system 100 includes a controller 118 and a control circuit 120 serving to control the power applied by the power supply 104 to the EAP actuator 116. When stimulated by an electric field, the EAP actuator 116 may exhibit a change in size and/or shape. For example, the electric field may cause the EAP actuator 116 to contract, in turn causing the normally flat beam 114 to deflect, and thereby causing the fan member 108 to move. The controller 118 may temporally vary the applied power with an operating frequency, fi; as a result, the fan members 108 may vibrate at a resonance frequency, f₂, corresponding to the operating frequency (e.g., f₂=f₁, f₂=2f₁, etc.). This consequently produces an air flow 122 near the heat-generating component 106 to dissipate heat. As depicted, the generated flow rate at position 124 typically increases with the distance D from the heat-generating component 106 due to viscous effects at the surface. Typically, the applied voltages may range from 1 V to 8000 V and the operating frequencies may range from 1 Hz to 10 KHz. In addition, the cooling system 100 may include one or more sensors 126 to provide feedback to the controller 118. For example, the sensor 126 may be a flow sensor that detects a flow parameter (e.g., a flow rate and/or a flow direction) produced by the benders 102. If the detected flow parameter reach a predetermined value, the controller 118 may maintain the amplitudes, frequencies, and/or phases applied to the benders 102. If, however, the detected flow parameter does not reach or if it exceeds the predetermined value, the controller 118 may adjust the applied amplitudes, frequencies, and/or phases until the detected flow parameter satisfies the predetermined value. In some embodiments, the sensor 126 is a temperature sensor. The controller 118 adjusts the power applied to the benders 102 by comparing the detected temperature to a desired temperature to ensure a cooling effect is satisfied.

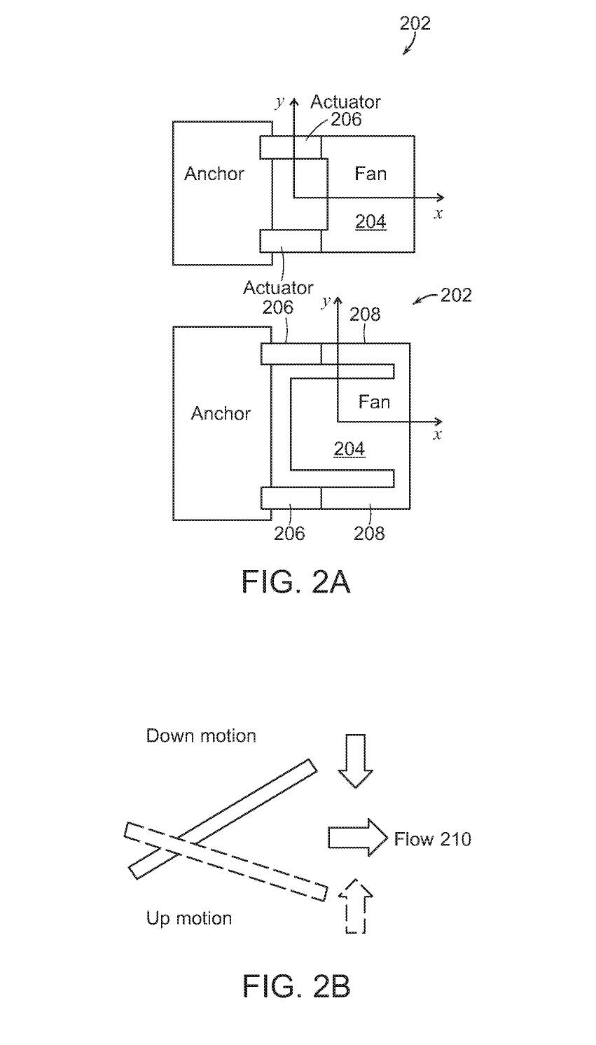

The benders 102 illustrated above represent exemplary embodiments only; they may include various configurations that are suitable for producing an air flow in an electronic device for heat dissipation and therefore are within the scope of the present invention. For example, referring to FIG. 2A, the bender 202 may include a fan member 204 and a pair of EAP actuators 206. When applying power to the pair of EAP actuators 206, they may change in size and/or shape and consequently cause the inclination thereof (and/or of the flexible beams 208 underlying of the actuators 206) to change through a range of motion during each actuation cycle (as depicted in FIG. 2B). The movement of the EAP actuators 206 and/or flexible beams 208 results in vibration of the fan member 204 and thereby produces an air flow 210.

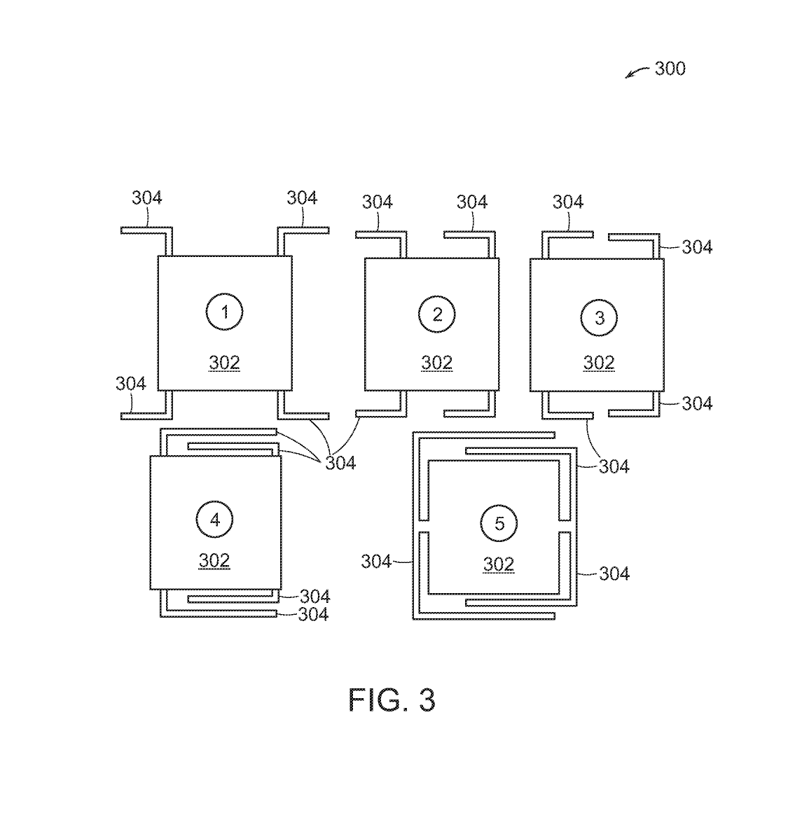

FIG. 3 depicts various alternative bender configurations 300 in accordance with an embodiment of the present invention, where each fan member 302 has four actuators 304 (and/or four flexible beams) for moving the bender. As illustrated, the actuators 304 can be arranged in various configurations around the fan member 302.

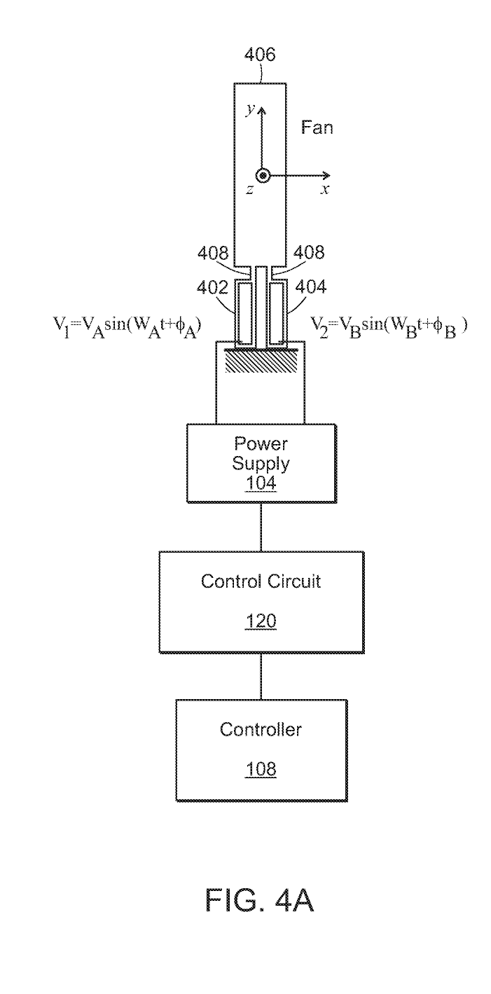

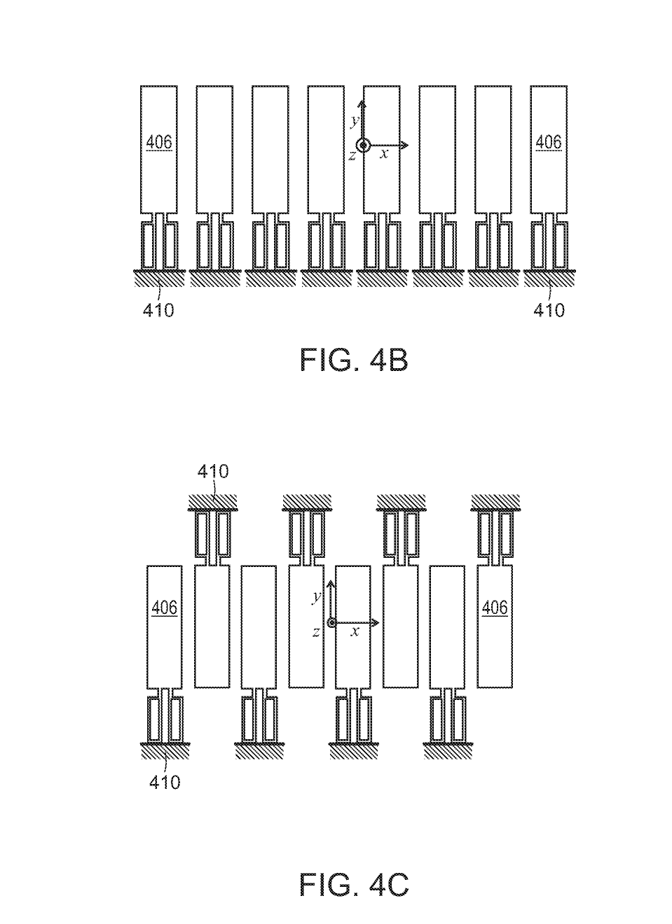

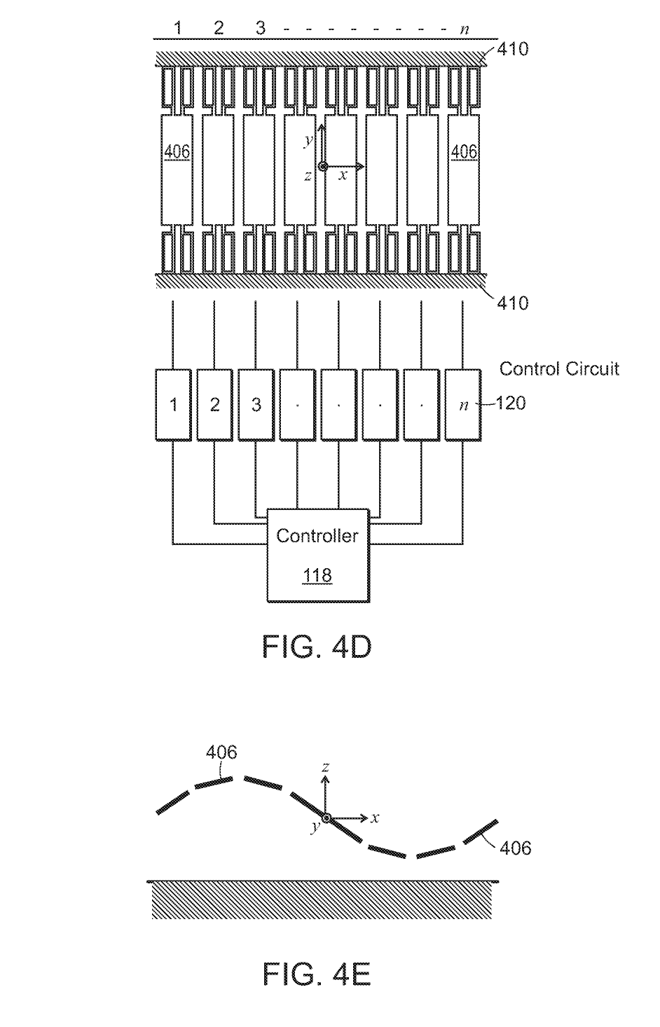

Referring to FIG. 4A, in one embodiment, the power applied to each of the EAP actuators 402, 404 is separately controllable, i.e., one of the EAP actuators 402, 404 may be activated at an amplitude, a phase, and/or a frequency that is independent of the amplitude, phase, and/or frequency applied to the other EAP actuators 402, 404. For n EAP actuators, the controller 118 may contain n control circuits each comprising a phase-delay circuit and driving one of the EAP actuators with the respective phase. The controller 118 may split a control signal, typically in the range from 1 Hz to 10 KHz, into n channels for the n control circuits 120 for separately controlling each of the EAP actuators. For example, the controller 118 may be configured to activate the individual EAP actuators 402, 404 of the array at the same frequency (i.e., ω_{A}=ω_{B}), but at different phases (i.e., φ_{A} and φ_{B}, respectively) and different amplitudes (i.e., V_{A} and V_{B}, respectively). In another example, the controller 118 may activate the EAP actuators 402, 404 at the same frequency (i.e., ω_{A}=ω_{B}) and same amplitude (i.e., V_{A}=V_{B}), but at different phases (i.e., φ_{A} and φ_{B}, respectively). By adjusting the amplitudes, frequencies and/or phases applied to each actuator 402, 404, the fan member 406 may move, including deflecting, twisting, rotating, and/or vibrating, to create a desired flow parameter (e.g., a flow rate or a flow direction).

When simultaneously applying in-phase power (i.e., φ_{A}=φ_{B}) at the same frequency to the pair of EAP actuators 402, 404, the motion of the fan member 406 has two degrees of freedom, including deflection in the vertical (z) direction and rotation (or tilting) around the x axis. If, however, the EAP actuators 402, 404 are operated with a phase shift therebetween (e.g., φ_{A} and φ_{B} have a phase difference of 180°), the motion of the fan member 406 may include an extra degree of freedom—i.e., rotation around the y axis. In one embodiment, the flexible beams 408 includes a highly compliant material (e.g., an AEP) that allows the fan member 406 to rotate through a large angle (e.g., 45°) around the y axis to enhance the produced air flow.

The benders may be arranged in various configurations. For example, referring to FIGS. 4B and 4C, each fan member 406 may be affixed to a substrate 410 on one side only. The fan members 406 may be oriented parallel to one another, where the same side of each fan member is clamped to the substrate 410 (FIG. 4B); or the fan members 406 may be anti-parallel to one another, where the opposite sides of two neighboring fan members 406 are clamped to the substrate 410 (FIG. 4C). In the embodiment shown in FIG. 4D, two opposite sides of the fan members 406 are both attached to the common substrate 410. One of ordinary skill in the art will understand that the illustrated bender array may have more configurations, i.e., the benders may be arranged in any manner that is suitable for producing a desired flow parameter(s) (e.g., a desired flow rate and/or a flow direction).

In various embodiments, the power applied to the benders is separately controllable, i.e., each bender may be activated at amplitudes, phases, and/or frequencies that are independent of the amplitudes, phases, and/or frequencies applied to the other benders. For n benders, the controller 118 may split a control signal into n channels for n control circuits, each control circuit associated with a bender, for separately controlling each of the benders. For example, the controller 118 may be configured to actuate the benders of the array at the same frequency and amplitude, but at different phases. As a result, with reference to FIG. 4E, the fan members 406 of the benders may move in the z direction and rotate around the y axis to various degrees, depending on the phases applied thereto, and thereby form a “wave” travelling in the x direction. This design may create an efficient air flow for heat dissipation. Additionally, the “wavelength” of the travelling “wave” may be adjusted by changing, for example, the width of the fan members and/or the number of fans per unit length, to produce a desired flow parameter.

In one embodiment, the controller 118 groups the fan members 406 into multiple subsets, each corresponding to fan members separated by a distance corresponding to the wave period; each subset is sequentially activated to produce the illustrated wave-like behavior and thereby achieve a predetermined flow parameter. Alternatively, each subset of the fan members 406 may be activated randomly or in any desired manner to individually or collectively create an air flow at one or more locations near the heat-generating component. In sum, the present invention provides an approach enabling the controller 118 to repeatedly activate individual fan members 406 or subsets thereof in a synchronized or unsynchronized manner to generate synchronized or unsynchronized vibration. In other embodiments, the controller 118 actuates the benders via a single control circuit 120—i.e., the benders are simultaneously activated at the same amplitude with the same frequency and same phase; this obviates the need of multiple control circuits 120, thereby simplifying the circuitry design.

The controller 118 desirably provides computational functionality, which may be implemented in software, hardware, firmware, hardwiring, or any combination thereof, to compute the required frequencies and amplitudes for a desired flow parameter. In general, the controller 118 may include a frequency generator, phase delay circuitry, and/or a computer (e.g., a general-purpose computer) performing the computations and communicating the frequencies, phases and amplitudes for the individual EAP actuators 116 to the power supply 104. For embodiments in which the functions are provided as one or more software programs, the programs may be written in any of a number of high level languages such as FORTRAN, PASCAL, JAVA, C, C++, C#, BASIC, various scripting languages, and/or HTML. Additionally, the software can be implemented in an assembly language directed to the microprocessor resident on a target computer; for example, the software may be implemented in Intel 80×86 assembly language if it is configured to run on an IBM PC or PC clone. The software may be embodied on an article of manufacture including, but not limited to, a floppy disk, a jump drive, a hard disk, an optical disk, a magnetic tape, a PROM, an EPROM, EEPROM, field-programmable gate array, or CD-ROM. Embodiments using hardware circuitry may be implemented using, for example, one or more FPGA, CPLD or ASIC processors. Such systems are readily available or can be implemented without undue experimentation.

The configurations of the benders provided herein are for illustration only, and the present invention is not limited to such configurations. One of ordinary skill in the art will understand that any variations are possible and are thus within the scope of the present invention. For example, the number of benders per electronic device, the configuration of the bender array, and/or the size, shape or orientation of the benders may be modified in any suitable manner for generating an air flow to dissipate heat generated in the electronic device. In addition, the controller 118 may actuate the EAP actuators 116 associated with the fan members to create movements of the fans simultaneously, sequentially, or in any desired manner to collectively produce a desired flow parameter (e.g., a flow rate and/or a flow direction).

Additionally, the benders may not be necessarily supplied by a power source—i.e., they may be static. In some embodiments, by adjusting the shape, size, and/or orientation of each bender, the density of the bender array (i.e., the number of benders per unit area), and/or the distance between the benders to the heat-generating component, the presence of the bender array itself is sufficient to produce a cooling effect. Without being bound to any particular theory or mechanism, this may be caused by, for example, efficient heat dissipation by the high thermal conductive surface area and varied geometry of the benders and/or bender motion resulting from a thermal gradient across the benders created by the heat-generating component 106. The thermal gradient may be self-reinforcing as air is forced through the narrow channels beneath the benders.

### B. Materials and Methods of Manufacture

Embodiments of the cooling systems in the present invention may be manufactured utilizing techniques including, but not limited to, MEMS and/or other suitable manufacturing techniques. The use of MEMS technology advantageously allows the cooling system to be manufactured in a sufficiently compact size such to be accommodated in devices having severe space constraints. In one embodiment, the fan member, flexible beam and anchor are fabricated from a single material (using a MEMS fabrication process), and the actuator material is applied thereto by deposition, screening, or other suitable application process. If the substrate is silicon (Si), selective masking and etching steps may be employed to fabricate the fan and beam members directly from the substrate surface. The actuators may include or consist essentially of any materials that exhibit a change in size or shape when stimulated by an electric field, and provide advantages over some traditional electroactive materials such as electro-ceramics for MEMS device applications due to their high strain, light weight, flexibility and low cost. The actuators may be divided into two classes: electrochemical (also known as “wet” or “ionic”) and field-activated (also known as “dry” or “electronic”). Electrochemical polymers use electrically driven mass transport of ions to effect a change in shape (or vice versa). Field-activated polymers use an electric field to effect a shape change by acting on charges within the polymer (or vice versa).

One of the most widely exploited polymers exhibiting ferroelectric behavior is poly(vinylidene fluoride), a family of polymers commonly known as PVDF, and its copolymers. These polymers are partly crystalline and have an inactive amorphous phase. Their Young's moduli are between 1 and 10 GPa. This relatively high elastic modulus offers a correspondingly high mechanical energy density, so that strains of nearly 7% can be induced. Recently, P(VDF-TrFE-CFE) (a terpolymer) has been shown to exhibit relaxor ferroelectric behavior with large electrostrictive strains and high energy densities. All of these materials may be used advantageously in accordance herewith.

Exemplary techniques for manufacturing various components of the cooling system described herein are described below. They generally involve a polymer-based fabrication approach, where a metal layer is first deposited onto a polyimide, silicon or other suitable substrate, and the EAP materials are applied onto the formed metal layer. Thereafter, a second metal layer is applied to the exposed surface of the EAP polymer. The two metal layers serve as electrodes for applying an electric field to actuate the EAP polymer.

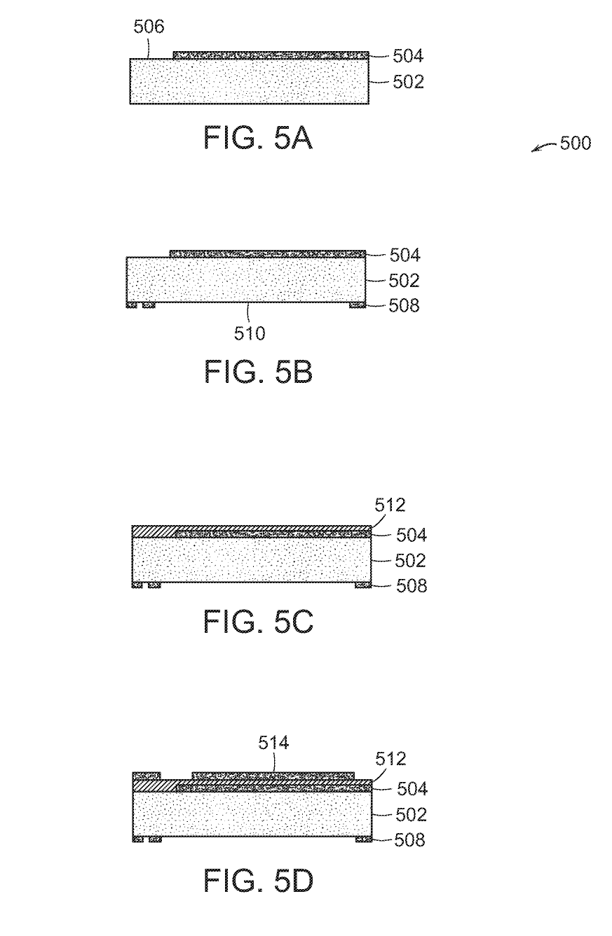

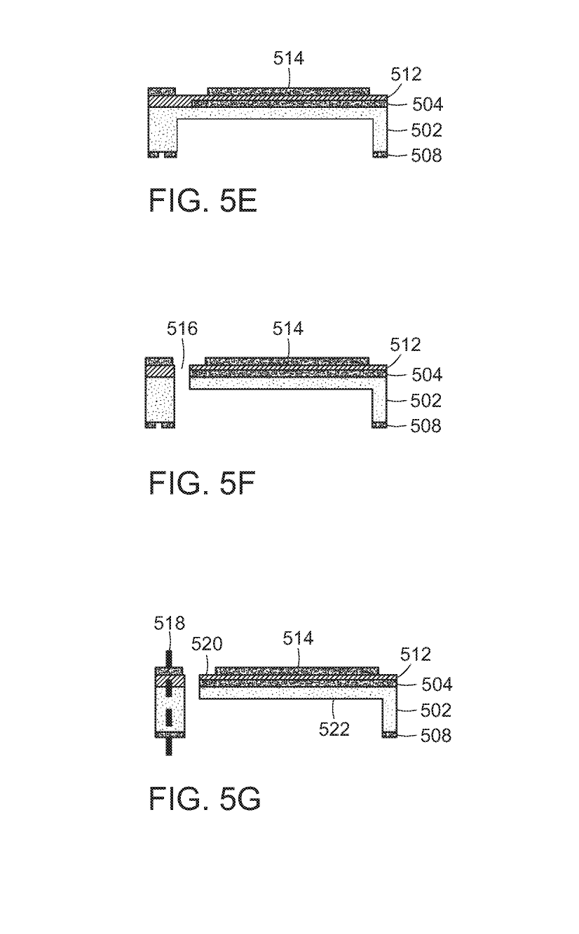

A first exemplary method 500 of manufacturing the benders of the cooling system using hybrid Si-Electroactive polymer MEMS in a wafer-level process is shown in FIGS. 5A-5G. In this embodiment, the bender fabrication process flow includes the steps of:

(a) forming a first electrode layer on a substrate (FIG. 5A): this step includes preparation of a silicon wafer substrate 502, deposition of a metal contact 504 (including a material such as Al, Ti, Ta, Au, Cr, Cu, etc. or a combination thereof) on the top side 506 of the substrate 502, and formation of a desired pattern of the first electrode layer 504 on the substrate 502 using a photolithography (PL) process and a metal etching (e.g., wet etching or reactive ion etching (RIE)) process. Alternatively, the metal deposition and photolithography process may be followed by a lift-off process to fabricate the metal pattern. In some embodiments, the metal pattern is created by a laser cut. Further, the first electrode layer 504 may include conducting polymers (e.g., polyaniline, polypyrrole (Ppy), PEDOT-PSS or the like). Alternatively, the first electrode layer 504 may include composites of the conducting polymers in combination with metal or with metal seeds.

(b) forming a hard mask on a backside of the substrate (FIG. 5B): this step includes deposition of a metal layer 508 (including a material such as Al, Ti, Ta, Au, Cr, Cu, etc. or a combination thereof) on the backside 510 of the substrate 502, and formation of a hard mask 508 for back side release purposes using photolithography and metal etching (e.g., wet or RIE) processes. Similar to the formation of the first electrode layer 504, the metal etching process here may be replaced by a lift-off process. Alternatively, the metal pattern on the backside may be created by a laser cut. Alternatively, the hard mask may be a photoresist (PR) patterned using PL.

(c) depositing an EAP layer on the first electrode layer (FIG. 5C): this step includes deposition of EAP materials 512 (e.g., one or more P(VDF-TRFE-CFE) terpolymers) on the first electrode layer 504 (by spin coating, spray coating, rolling or nanoimprint lithography (NIL)), curing of the EAP materials (in an oven, a belt oven, or on a hot plate), and/or a polling process.

(d) forming a second electrode layer on the EAP layer (FIG. 5D): this step includes deposition of a second layer of metal contact (having a material such as Al, Ti, Ta, Au, Cr, Cu, etc.) on the EAP layer 512 formed in step (c), and formation of a desired pattern of the second electrode layer 514 using photolithography and metal etching (e.g., wet etching or RIE) processes. Similar to the formation of the first electrode layer 504, the metal deposition and photolithography processes may be followed by a lift-off process to fabricate the metal pattern of the second electrode layer 514. Alternatively, the metal pattern of the second electrode layer 514 may be created by a laser cut. Again, the second electrode layer 514 may also include (i) conducting polymers (e.g., polyaniline, PPy, PEDOT-PSS or the like) or (ii) composites of the conducting polymers in combination with metal or with metal seeds.

(e) releasing the backside wafer (FIG. 5E): this step includes release of the backside wafer substrate using, for example, a deep reactive-ion etching (DRIE) process. This step creates the final, desired thickness of the cooling components on the silicon device.

(f) releasing the EAP and substrate (FIG. 5F): this step includes release of the formed EAP and electrodes and the substrate using, for example, an EAP-RIE process followed by a through-silicon etching process 516 (using e.g., DRIE).

(g) separating the final cooling components (FIG. 5G): this step includes application of a cutting, scribing, cleaving, and/or breaking technique 518 on the wafer to separate the formed cooling components.

Note that the drawings herein do not necessarily represent the actual scales of various components in the cooling systems. For example, the fan member 520 may have comparable or larger dimensions than those of the EAP actuator 522.

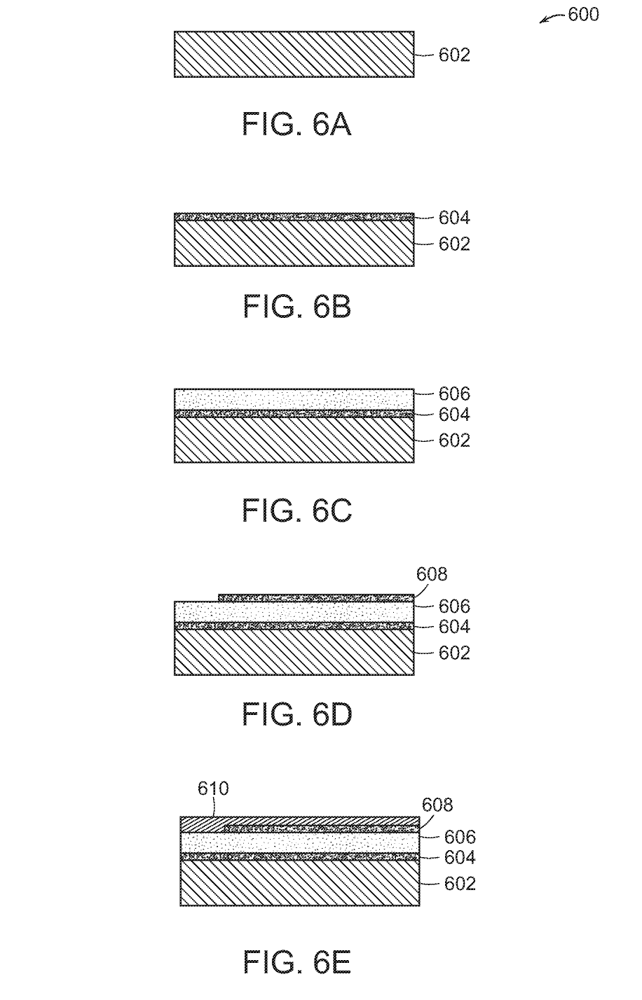

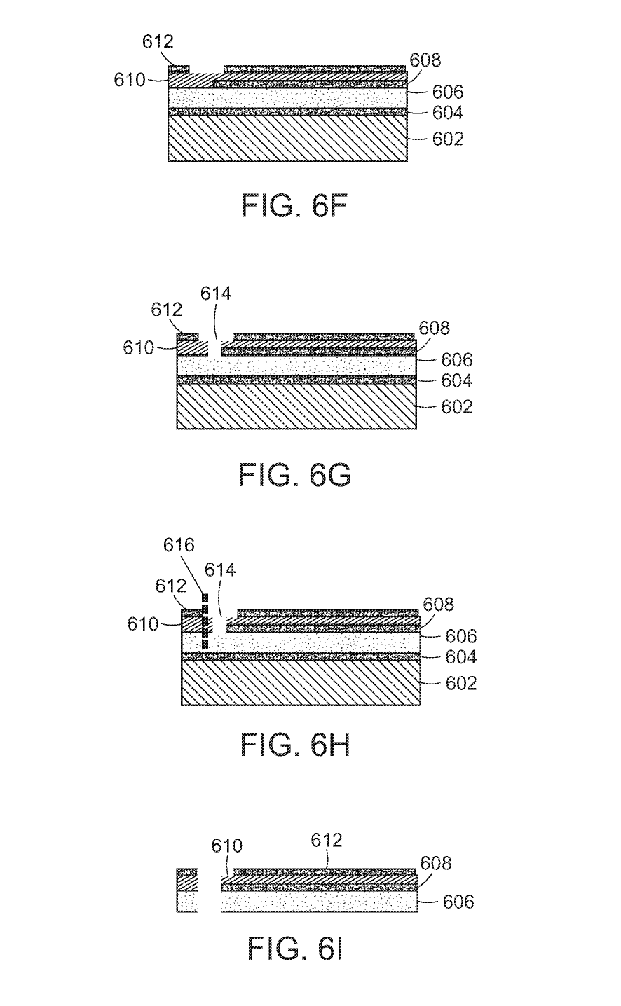

A second exemplary method 600 of manufacturing the benders of the cooling system using all polymer MEMS is shown in FIGS. 6A-6I. In this embodiment, the bender fabrication process flow includes the steps of:

(a) preparing an interim substrate (FIG. 6A): this step includes preparation of an interim substrate 602 that may include any substrate (such as, semi-conductor wafer, metal, glass, quartz, ceramic, polyimide, or another polymer substrate) having a flat surface.

(b) depositing a sacrificial layer on the substrate (FIG. 6B): this step includes application of a coating layer (using, e.g., OmniCoat or other materials) on the substrate 602 to form a sacrificial layer 604.

(c) forming a passive polymer sheet layer (FIG. 6C): this step includes application of a passive polymer (e.g., polyimide) on the sacrificial layer 604 by rolling, spin coating, or spray coating to create a passive polymer sheet layer 606. Because the passive polymer layer 606 has a thickness of the final device, it may not be thinned or etched during the fabrication process. Its surface, however, may be modified or functionalized (e.g., modifying the surface energy and/or chemical and physical affinity thereof) to increase the attachment between neighboring layers.

(d) forming a first electrode layer (FIG. 6D): this step includes deposition of a metal contact (including a material such as Al, Ti, Ta, Au, Cr, Cu, etc.) on the passive polymer sheet layer 606, and formation of the a desired pattern of the first electrode layer 608 using photolithography and metal etching (e.g., wet etching or RIE) processes. Alternatively, the metal pattern may be created by a laser cut. In some embodiments, the metal pattern includes (i) conducting polymers (e.g., polyaniline, PPy, PEDOT-PSS or the like) or (ii) composites of the conducting polymers in combination with metal or with metal seeds.

(e) depositing an EAP layer on the first electrode layer (FIG. 6E): this step includes deposition of EAP materials 610 on the first electrode layer 608 (by spin coating, spray coating, rolling or NIL) and curing of the EAP materials (in an oven, a belt oven, or on a hot plate).

(f) forming a second electrode layer (FIG. 6F): this step includes deposition of a second layer of metal contact (having a material such as Al, Ti, Ta, Au, Cr, Cu, etc.) on the EAP layer 610 formed in step (e), and formation of a desired pattern of the second electrode layer 612 using photolithography and metal etching (e.g., wet etching or RIE) processes. Similar to the formation of the first electrode layer 608, the metal pattern of the second electrode layer 612 may be created by a laser cut. In one embodiment, the second electrode layer 612 includes (i) conducting polymers (e.g., polyaniline, PPy, PEDOT-PSS or the like) or (ii) composites of the conducting polymers in combination with metal or with metal seeds.

(g) forming a via in the EAP layer (FIG. 6G): this step includes formation of a via 614 in the EAP layer 610 using a laser or any other suitable technique.

(h) cutting through multiple layers to form a final cooling component (FIG. 6H): this step includes cutting through multiple layers, including the passive polymer sheet layer 606 and/or the electrode layer(s), using a laser or any appropriate technique to form a final device.

(i) releasing the final cooling component (FIG. 61): this step includes removal of the sacrificial layer 604 from the substrate 602 to release the final cooling component.

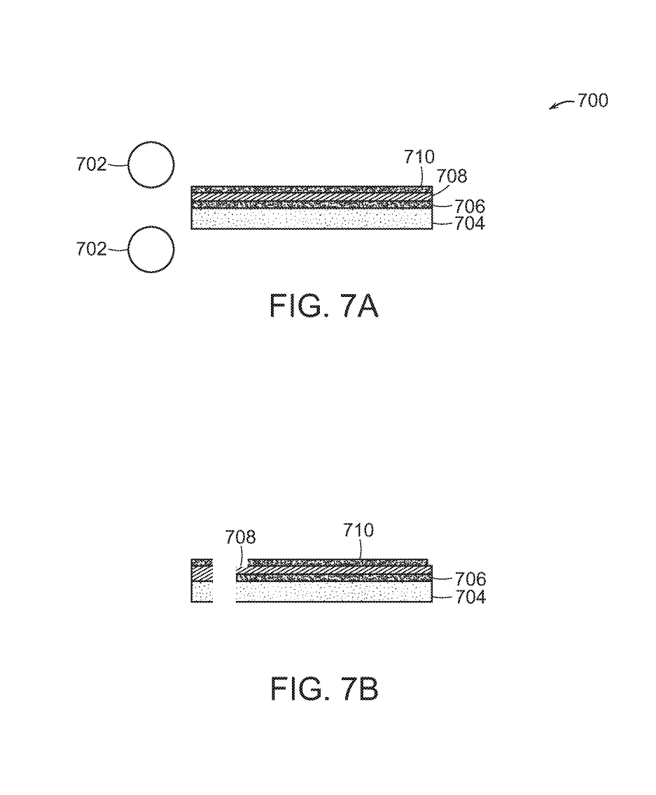

A third exemplary method 700 of manufacturing the benders of the cooling system using an industrial roll-to-roll process 702 is shown in FIGS. 7A and 7B. In this embodiment, the bender fabrication process flow includes the steps of:

(a) preparing a polymer sheet layer: this step includes preparation of a polymer (e.g., polyimide) sheet layer 704 that typically has a flat surface.

(b) forming a first electrode layer: this step includes application of a metal contact 706 (including a material such as Al, Ti, Ta, Au, Cr, Cu, etc.) on the polymer sheet layer 704 formed in step (a) using the roll-to-roll process.

(c) forming an EAP layer on the first electrode layer: this step includes application of EAP materials 708 on the first electrode layer 706 using the roll-to-roll process and curing of the EAP materials (in an oven, a belt oven, or on a hot plate).

(f) forming a second electrode layer: this step includes application of a metal contact 710 (including a material such as Al, Ti, Ta, Au, Cr, Cu, etc.) on the EAP layer 708 using the roll-to-roll process.

(g) separating the final cooling components: this step includes application of a selective laser drill to produce the final cooling components.

It should be noted that the methods of manufacturing the cooling systems described herein are presented as representative examples, and any of the cooling systems and/or components thereof may be formed using any of the manufacturing methods described, as appropriate, or other suitable methods. For example, another mode of manufacture may include silicon and polymer cantilever technologies. In a silicon-based approach, the fan and beam members are separated from a silicon substrate in the manner of forming a resonator window (e.g., using a suitable etch), as is well understood by those skilled in MEMS device fabrication, and a well is etched into the beam. Electrodes are deposited onto the well floor, and the well is filled with the EAP materials (which is subsequently cured).

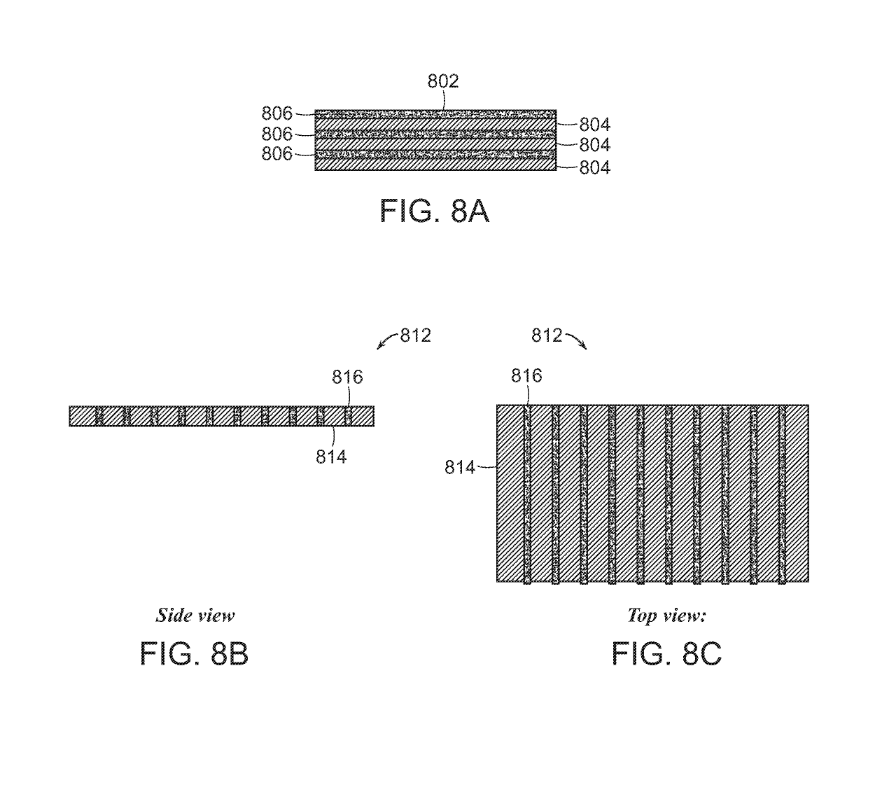

Further, each EAP actuator may include multiple conductive contacts to increase the efficiency thereof. Referring to FIG. 8A, in some embodiments, the EAP actuator 802 includes multiple EAP layers 804 and multiple horizontal conductive layers 806 that are connected to a common port (not shown). The EAP layers 804 and conductive layers 806 are interleaved to form a sandwich configuration. The numbers of the EAP layers 804 and the conductive layers 806 may be determined based on the thickness thereof, the electro-mechanical properties of the EAP materials, the layout and/or electrical specifications of the electronic devices in which they are deployed, etc. With reference to FIGS. 8B and 8C, in other embodiments, the EAP actuator 812 includes an EAP layer 814 having an array of vertical conductive lines 816 embedded therein. Similarly, the conductive lines 816 are connected to a common port. The number of conductive lines 816 in the EAP layer 814 may, again, be determined based on the thickness and/or electro-mechanical properties of the EAP layer 814, the layout and/or electrical specifications of the electronic devices in which they are deployed, etc.

The terms and expressions employed herein are used as terms and expressions of description and not of limitation, and there is no intention, in the use of such terms and expressions, of excluding any equivalents of the features shown and described or portions thereof. In addition, having described certain embodiments of the invention, it will be apparent to those of ordinary skill in the art that other embodiments incorporating the concepts disclosed herein may be used without departing from the spirit and scope of the invention. Accordingly, the described embodiments are to be considered in all respects as only illustrative and not restrictive.

What is claimed is:

1. A cooling device comprising:
a substrate;
arranged on the substrate, a plurality of benders each comprising (i) a fan member, (ii) a beam, and (iii) at least one electroactive actuator associated with the beam for transmitting force thereto, the beam being anchored to the substrate, and the fan member and the electroactive actuator being unanchored to the substrate;
supply circuitry for supplying a time-varying signal to the electroactive actuators, whereby the fan members vibrate at a frequency corresponding to the signal and collectively produce an air flow.

2. The device of claim 1, wherein the benders all have a common orientation on the substrate so that the flows produced by the benders are substantially additive.

3. The device of claim 1, wherein at least some of the benders have different orientations on the substrate.

4. The device of claim 1, wherein vibration of the benders are synchronized.

5. The device of claim 1, wherein vibration of the benders are unsynchronized.

6. The device of claim 1, wherein the electroactive actuator is mechanically coupled to the beam.

7. The device of claim 1, wherein the beam is made of an electroactive polymer.

8. The device of claim 1, further comprising control circuitry for selectively operating a subset of the benders to achieve a predetermined flow parameter.

9. The device of claim 8, wherein the flow parameter comprises at least one of a flow rate or a flow direction.

10. The device of claim 1, further comprising control circuitry for independently operating each of the benders to achieve a predetermined flow parameter.

11. The device of claim 10, wherein at least some of the time-varying signals applied to the electroactive actuators have a phase difference.

12. The device of claim 10, wherein at least some of the time-varying signals applied to the electroactive actuators have an amplitude difference.

13. The device of claim 1, further comprising control circuitry for grouping the benders into a plurality of subsets of the benders and independently operating each subset to achieve a predetermined flow parameter.

14. The device of claim 13, wherein vibration of the benders in each subset of the benders are synchronized.

15. The device of claim 13, wherein vibration of the benders between different subsets of the benders are synchronized.

16. The device of claim 13, wherein at least some of the time-varying signals applied to the subsets of the electroactive actuators have a phase difference.

17. The device of claim 13, wherein at least some of the time-varying signals applied to the subsets of the electroactive actuators have an amplitude difference.

18. The device of claim 1, wherein each electroactive actuator comprise a plurality of electroactive layers and a plurality of conductive layers.

19. The device of claim 1, wherein the electroactive actuator comprises an electroactive layer and a plurality of conductive lines embedded therein.

20. The device of claim 1, further comprising a flow sensor for detecting a parameter associated with the produced air flow.

21. The device of claim 1, further comprising a temperature sensor for detecting a temperature associated with the cooling device, a platform thereof, or an ambient environment.

22. A method of cooling a system, the method comprising:
providing a cooling device comprising a substrate and a plurality of benders arranged on the substrate, each bender comprising (i) a fan member, (ii) a beam, and (iii) at least one electroactive actuator associated with the beam for transmitting force thereto, the beam being anchored to the substrate, and the fan member and the electroactive actuator being unanchored to the substrate; and
applying a time-varying signal to the electroactive actuators to cause vibration of the fan members at a frequency corresponding to the signal and collectively produce an air flow.

23. A method of manufacturing a cooling device, the method comprising:
providing a substrate; and
forming, on the substrate, a plurality of benders, each comprising (i) a fan member, (ii) a beam, and (iii) at least one electroactive polymer associated with the beam for transmitting force thereto.

24. The method of claim 23, wherein the plurality of benders are formed utilizing micro-electromechanical system (MEMS) technology.

25. The method of claim 23, wherein the substrate comprises at least one of a semi-conductor wafer, metal, glass, quartz, ceramic, or a polymer.

26. The method of claim 23, wherein formation of the benders comprises the steps of:
forming a first electrode layer on a first side of the substrate;
forming a hard mask on a second side of the substrate;
depositing the electroactive polymer on the first electrode layer;
forming a second electrode layer;
releasing a portion of the substrate on the second side thereof;
releasing the electroactive polymer; and
separating the plurality of the benders.

27. The method of claim 26, wherein at least one of the first electrode layer or the second electrode layer is formed by at least one of a photolithography process, a metal etching process, a lift-off process, or a laser cut.

28. The method of claim 26, wherein the electroactive polymer is deposited by at least one of spin coating, spray coating, rolling or nanoimprint lithography.

29. The method of claim 23, wherein formation of the benders comprises the steps of:
depositing a sacrificial layer on the substrate;
forming a polymer sheet layer;
forming a first electrode layer;
depositing the electroactive polymer on the first electrode layer;
forming a second electrode layer;
forming a via;
separating the plurality of the benders; and
removing the a sacrificial layer to release the benders.

30. The method of claim 23, wherein formation of the benders comprises the steps of:
depositing a sacrificial layer on the substrate;
forming a polymer sheet layer;
forming a first electrode layer;
depositing the electroactive polymer on the first electrode layer;
forming a second electrode layer;
forming a via;
separating the plurality of the benders; and
removing the a sacrificial layer to release the benders.

31. The method of claim 23, wherein formation of the benders comprises the steps of:
forming a first electrode layer on the substrate;
depositing the electroactive polymer on the first electrode layer;
forming a second electrode layer; and
separating the plurality of the benders.
